(19) United States
(12) Patent Application Publication
(10) Pub. No.: US 2026/0170198 A1
(43) Pub. Date: Jun. 18, 2026

(54) OPTIMIZATION OF SOLAR ENERGY COLLECTION

(71) Applicant: International Business Machines Corporation, Armonk, NY (US)

(72) Inventors: Sarbajit Kumar Rakshit, KOLKATA (IN); Manikandan Padmanaban, Chennai (IN); Jagabondhu Hazra, BANGALORE (IN)

(73) Assignee: International Business Machines Corporation, Armonk, NY (US)

(21) Appl. No.: 18/985,767

(22) Filed: Dec. 18, 2024

(51) Int. Cl. G06F 30/20

(52) U.S. Cl. CPC G06F 30/20

(57) ABSTRACT

An embodiment constructs a model of atmospheric dust over a solar farm. Using the model of atmospheric dust, the embodiment predicts solar irradiance and cell soiling in an area of a solar farm. The embodiment generates a solar collection prediction for the area based on the solar irradiance and cell soiling. The embodiment makes a modified prediction based on cloud seeding over the area. Responsive to the modified prediction, the embodiment sends an instruction for cloud seeding over the area.

### BACKGROUND

The present invention relates generally to facilities management. More particularly, the present invention relates to a method, system, and computer program for predicting the effects of cloud seeding on banks of deployed solar cells.

Solar power is the conversion of sunlight into electricity. Photovoltaic (PV) systems convert solar irradiance into useful electrical energy using the photovoltaic effect. While variability in solar output due to changes in the sun's position throughout the day and throughout the seasons is predictable, changes in ground-level irradiance due to clouds and local weather conditions creates uncertainty that makes modeling and predicting solar power generation difficult.

“Solar farms” are areas of land where banks of PV cells are deployed to provide large-scale power generation. Many solar farms are in an environments in which atmospheric particulate matter is a significant hazard. Particles in the atmosphere may greatly reduce the ground-level irradiance. Particles that land and accumulate on the solar panels may also reduce the energy generated by the panels (an effect known as “PV soiling”). The air quality in these “dusty” environments reduces the benefit of deploying the cells in a location with ample sunlight and sparse cloud cover, which is otherwise ideal for solar cells.

### SUMMARY

The illustrative embodiments provide for optimization of solar energy collection. An embodiment includes constructing a model of atmospheric dust over a solar farm. The embodiment also includes generating, using the model of the atmospheric dust, a solar irradiance prediction for a first area of a solar farm. The embodiment also includes generating cell soiling data for the first area of the solar farm, the cell soiling data based on images of solar cells within the first area of the solar farm. The embodiment also includes predicting, using the solar irradiance prediction and the cell soiling data as inputs to a prediction neural network, an initial solar collection prediction for the first area of the solar farm. The embodiment also includes modifying the initial solar collection prediction based on an effect of cloud seeding on the first area of the solar farm to produce a modified solar collection prediction. The embodiment also includes sending, responsive to the modified solar collection prediction, an instruction for cloud seeding the first area of the solar farm. Other embodiments of this aspect include corresponding computer systems, apparatus, and computer programs recorded on one or more computer storage devices, each configured to perform the actions of the embodiment.

An embodiment includes a computer usable program product. The computer usable program product includes a computer-readable storage medium, and program instructions stored on the storage medium.

An embodiment includes a computer system. The computer system includes a processor, a computer-readable memory, and a computer-readable storage medium, and program instructions stored on the storage medium for execution by the processor via the memory.

### BRIEF DESCRIPTION OF THE DRAWINGS

The novel features believed characteristic of the invention are set forth in the appended claims. The invention itself, however, as well as a preferred mode of use, further objectives, and advantages thereof, will best be understood by reference to the following detailed description of the illustrative embodiments when read in conjunction with the accompanying drawings, wherein:

FIG. 1 depicts a block diagram of a computing environment in accordance with an illustrative embodiment;

FIG. 2 depicts a block diagram of an example solar farm in accordance with an illustrative embodiment;

FIG. 3 depicts a block diagram of an example solar farm control infrastructure in accordance with an illustrative embodiment;

FIG. 4 depicts a block diagram of an example solar collection prediction process in accordance with an illustrative embodiment;

FIG. 5 depicts a block diagram of an example processing environment of a neural network in accordance with an illustrative embodiment;

FIG. 6 depicts a block diagram of an example training environment of a neural network in accordance with an illustrative embodiment; and

FIG. 7 depicts a block diagram of an example cost benefit map in accordance with an illustrative embodiment.

### DETAILED DESCRIPTION

Modern solar farms deploy large numbers of solar cells over many acres of land, with a variety of measurement and monitoring tools to accurately assess the collection of solar energy in each area within the solar farm. While these tools allow for attendants to address malfunctioning elements within the cell banks, the atmospheric conditions over the solar farm is usually seen as background information under which the solar farm operates. Excessive atmospheric dust reduces irradiance; excessive dust on solar panels must eventually be manually removed.

The present disclosure addresses the deficiencies described above by providing a process (as well as a system, method, machine-readable medium, etc.) that identifies opportunities to improve the performance of a solar farm through cloud seeding. Increased rainfall can both reduce atmospheric dust concentration and remove dust on solar panels.

Embodiments identify areas of the solar farm where the improvement to solar irradiance outweighs the costs of seeding.

The illustrative embodiments provide for optimization of solar energy collection. A “solar farm” as used herein is any facility that deploys and manages photovoltaic cells for the collection and distribution of solar energy.

The terms “particulate matter,” “atmospheric particles,” and “dust” are used interchangeably and generally for anything carried in the atmosphere that could interfere, in whole or in part, with the collection of solar power.

Illustrative embodiments include establishing a model based at least in part on performance parameters on a solar farm. Inputs to the model include mechanical, electrical, geographical, temporal, meteorological, and other data.

Illustrative embodiments include predicting solar energy collection from PV cells based on particulate matter in the atmosphere and/or accumulated on the PV cells based on expected weather patterns. Available remediation actions, such as cloud seeding, are evaluated against the expected outcome. establishing a knowledge base based at least in part on sensor data received from a network. The knowledge base comprises network data representative of a plurality of entities in the network and relationships among the plurality of entities in the network. An entity as referred to herein is any network component of interest represented as a node in the knowledge graph and will generally be a source of data or described by another source of data.

For the sake of clarity of the description, and without implying any limitation thereto, the illustrative embodiments are described using some example configurations. From this disclosure, those of ordinary skill in the art will be able to conceive many alterations, adaptations, and modifications of a described configuration for achieving a described purpose, and the same are contemplated within the scope of the illustrative embodiments.

Furthermore, simplified diagrams of the data processing environments are used in the figures and the illustrative embodiments. In an actual computing environment, additional structures or components that are not shown or described herein, or structures or components different from those shown but for a similar function as described herein may be present without departing the scope of the illustrative embodiments.

Furthermore, the illustrative embodiments are described with respect to specific actual or hypothetical components only as examples. Any specific manifestations of these and other similar artifacts are not intended to be limiting to the invention. Any suitable manifestation of these and other similar artifacts can be selected within the scope of the illustrative embodiments.

The examples in this disclosure are used only for the clarity of the description and are not limiting to the illustrative embodiments. Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed above.

Furthermore, the illustrative embodiments may be implemented with respect to any type of data, data source, or access to a data source over a data network. Any type of data storage device may provide the data to an embodiment of the invention, either locally at a data processing system or over a data network, within the scope of the invention. Where an embodiment is described using a mobile device, any type of data storage device suitable for use with the mobile device may provide the data to such embodiment, either locally at the mobile device or over a data network, within the scope of the illustrative embodiments.

The illustrative embodiments are described using specific code, computer readable storage media, high-level features, designs, architectures, protocols, layouts, schematics, and tools only as examples and are not limiting to the illustrative embodiments. Furthermore, the illustrative embodiments are described in some instances using particular software, tools, and data processing environments only as an example for the clarity of the description. The illustrative embodiments may be used in conjunction with other comparable or similarly purposed structures, systems, applications, or architectures. For example, other comparable mobile devices, structures, systems, applications, or architectures therefor, may be used in conjunction with such embodiment of the invention within the scope of the invention. An illustrative embodiment may be implemented in hardware, software, or a combination thereof.

The examples in this disclosure are used only for the clarity of the description and are not limiting to the illustrative embodiments. Additional data, operations, actions, tasks, activities, and manipulations will be conceivable from this disclosure and the same are contemplated within the scope of the illustrative embodiments.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media.

As will be understood by those of skill in the art, data is typically moved at some occasional points in time during normal operations of a storage device, such as during access, de-fragmentation or garbage collection, but this does not render the storage device as transitory because the data is not transitory while it is stored.

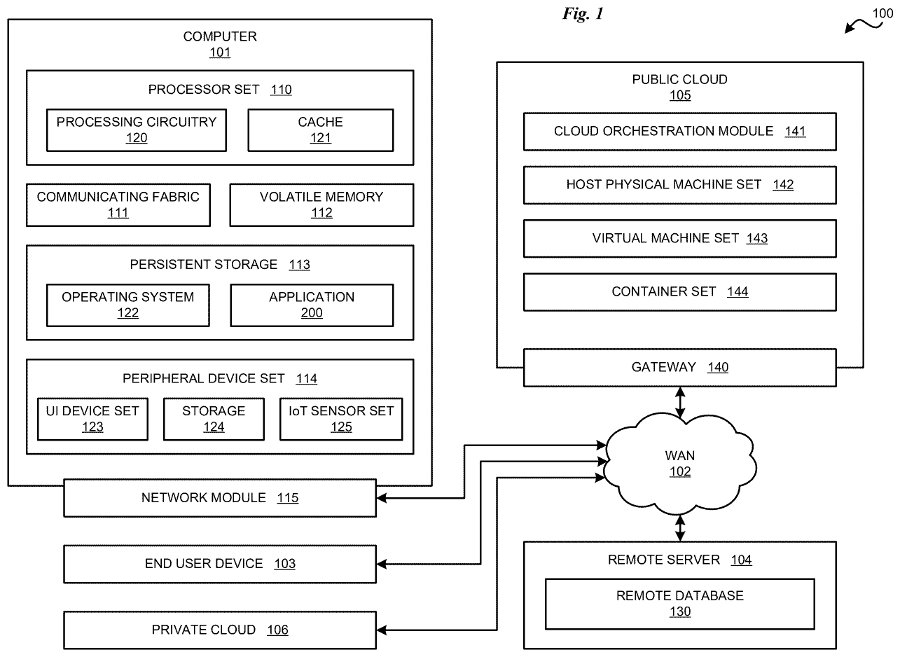

With reference to FIG. 1, this figure depicts a block diagram of a computing environment 100. Computing environment 100 contains an example of an environment for the execution of at least some of the computer code involved in performing the inventive methods, such as a solar collection management module 200 that projects energy output based on solar farm status and conditions, determines the effects of cloud seeding on the solar output, and sends instructions for selective cloud seeding when appropriate. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile.

In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 012 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Measured service: cloud systems automatically control and optimize resource use by leveraging a metering capability at some level of abstraction appropriate to the type of service (e.g., storage, processing, bandwidth, and active user accounts). Resource usage can be monitored, controlled, reported, and invoiced, providing transparency for both the provider and consumer of the utilized service.

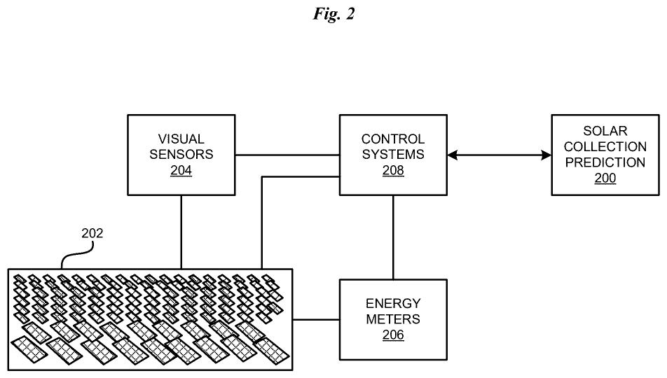

With reference to FIG. 2, this figure depicts a block diagram of an example solar farm 201 in accordance with an illustrative embodiment. In the illustrated embodiment, solar cell banks 202 are deployed to collect solar power. Visual sensors 204 capture the state of the solar cell banks 202. Energy meters 206 measure the power collection from the solar cell banks 202. Control systems 208 receive and transmit data from the sensors and meters associated with the solar farm as well as configuring the solar banks 202. The control systems 208 transmit collected data to the solar collection management module 200.

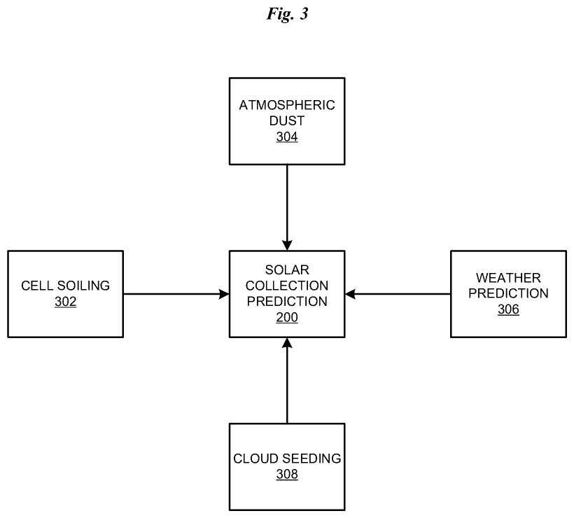

With reference to FIG. 3, this figure depicts a block diagram of an example solar farm control infrastructure 301 in accordance with an illustrative embodiment. In the illustrated embodiment, the solar farm control infrastructure 301 includes the solar collection management module 200 of FIG. 1. The solar collection management module 200 receives data from the solar farm 201 and combines it with other data sources to model the solar energy collection for the solar farm 201. A cell soiling module 302, an atmospheric dust module 304, a weather prediction module 306, and a cloud seeding module 308 each provide data to the solar collection management module 200.

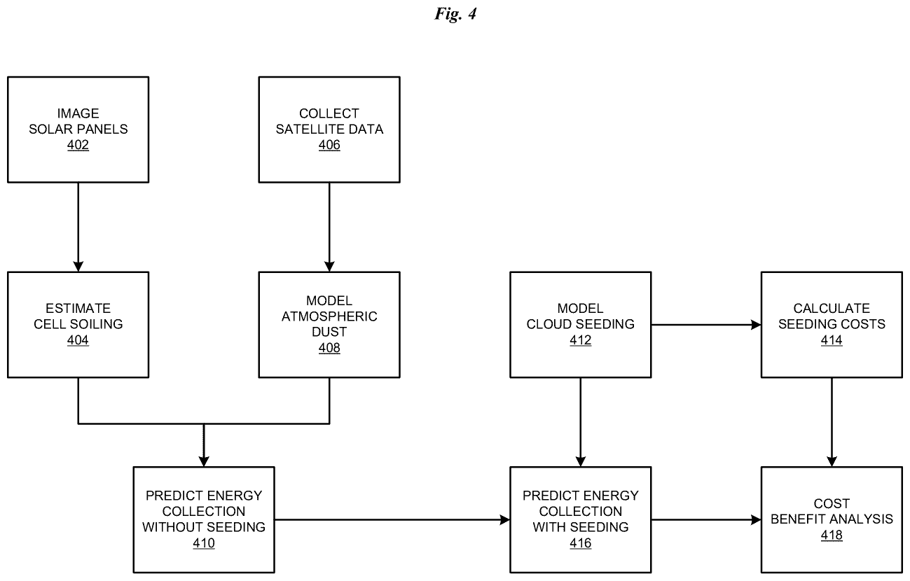

With reference to FIG. 4, this figure illustrates a flow diagram of an example process by which a solar collection management module 200 may make predictions. At step 402, visual sensors 204 capture images of the solar cell banks 202. The timeliness of the images may vary depending on the operation of the visual sensors. The most recent images may be used for each solar cell bank; in some implementations, a query for updated images may be sent if the images are out of date or of poor quality.

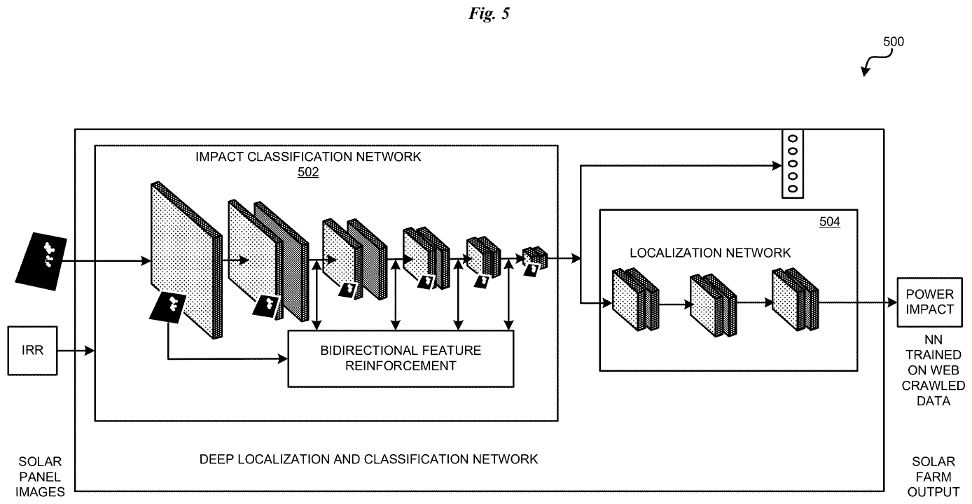

At step 404, the cell soiling module 302 uses the captured images in conjunction with other known data to determine the extent and nature of the soiling of the solar cells. A neural network may be used to determine cell soiling, as further described with respect to FIG. 5 below.

At step 406, satellite data is collected. This data is made regularly available through weather satellites and may include images in multiple spectra. In embodiments in which the satellite data is accessed from a third party, such as a government weather program or weather data service, pre-processing and metadata may also be included.

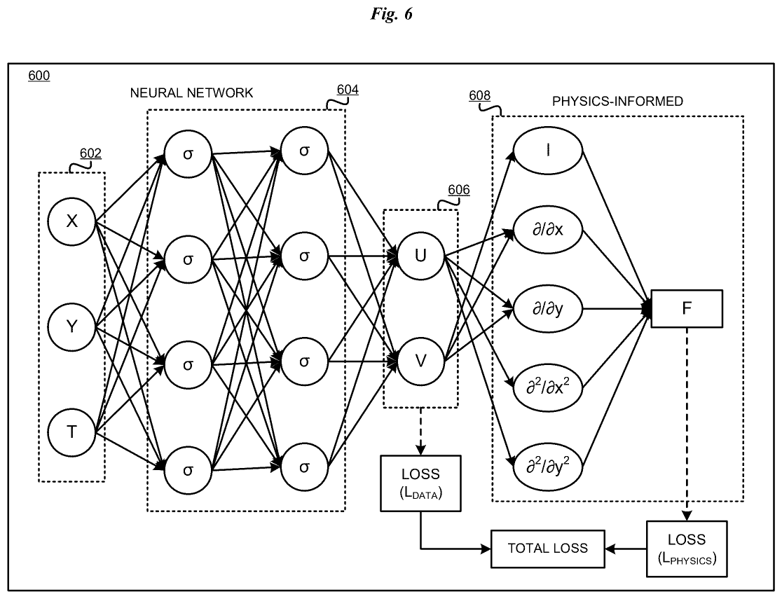

At step 408, the collected data is used by the atmospheric dust module 304 to model the particulate matter in the atmosphere above the solar farm. In addition to the collected data, the model may include known geographic and meteorological data for the area, and may incorporate stochastic elements such as likely wind and precipitation patterns for the region and season. More details of modeling atmospheric dust are described with respect to FIG. 6 below.

At step 410, the cell soiling and atmospheric dust models are used to predict energy collection by the solar cells, taking into account losses due to the condition of the cells and the atmospheric particles. The solar collection management module 200 may also take additional environmental and infrastructure factors into account, such as the optimal energy output, any control decisions made within the solar farm (such as angling or other adjustment of solar panels), and expected cloud cover and inclement weather. These predictions can be made across many cell banks, with individual conditions and energy projections made for each area within the solar farm.

At step 412, the cloud seeding module 308 identifies the possible application of cloud seeding services to areas of the solar farm. The cloud seeding module 308 may take into account geographic and meteorological features to determine what interventions are possible and prevent their likely effects. Different chemicals may be available and may be applied over selected areas in different concentrations based on many factors, such as the capacity of aerial delivery vehicles, wind and humidity profiles, the time of day, and local regulations.

At step 414, the cloud seeding module 308 further determines that costs associated with different cloud seeding services. Costs may be understood in terms of resource allocation and time as well as expense. The cost calculations may be summarized in terms of an estimated monetary amount, an energy amount, or in any units appropriate for comparison and analysis.

At step 416, the solar collection management module 200 receives the cloud seeding options from the cloud seeding module 308 and predicts solar collection for the available cell banks based on the cloud seeding data. For each area, the difference between solar energy output with and without cloud seeding is produced as the benefit of cloud seeding operations for that area.

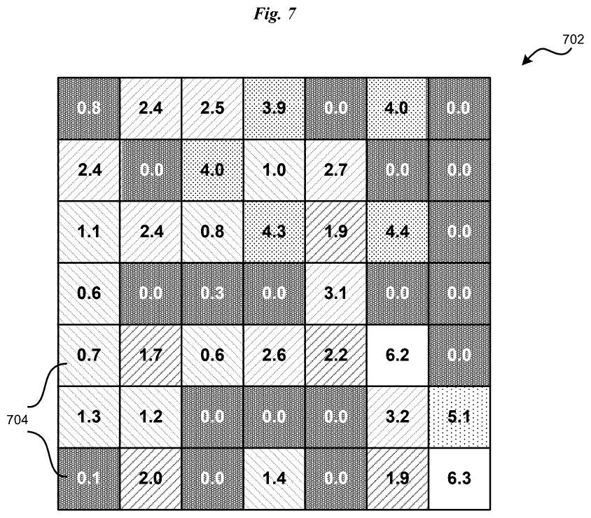

At step 418, a cost benefit analysis takes into account both the benefit in increased energy production of cloud seeding intervention and the cost of that intervention, as described with respect to FIG. 7 below.

With reference to FIG. 5, this figure illustrates the use of neural networks in determining cell soiling. An impact classification network 502 takes visual data and measured energy collection as inputs. The network 502 may receive other data, such as the local geography and geology relevant to identifying the particulate matter on the solar panels. The impact classification network 502 may be a recurrent neural network, characterized in using both feedforward and feedback steps to accurately determine the nature of the soiling. The output of the impact classification network 502 is then provided to the localization network 504, which locates the identified soiling on particular cells and/or cell banks relative to a larger area of the solar form or of the solar farm as a whole. The determined data, involving soiling and its effect on solar power collection, are provided to the solar collection management prediction module 200.

With reference to FIG. 6, a physics-informed learning model 600 can be used by the atmospheric dust module 304 in modeling the solar irradiance. The learning model 600 has the regular characteristics of a neural network, including inputs 602, nodes 604, and outputs 606. When training the network, an additional set of physics constraints 608 are added to optimize for solutions that match known physical properties of atmospheric particulate matter. For example, the following sum of three separate loss functions may be minimized:

$${}_{θ}^{min} L ( \tilde{y} , {y}_{θ} ) + λ {L}^{( mass )} ( {y}_{θ} ) + μ {L}^{( pos )} ( {y}_{θ} )$$

Where L is the conventional loss function, L(mass) penalizes a change in particulate mass, and L(pos) penalizes negative values for mass and/or concentration of particulates. The resulting reduction in solar irradiance predicted by the atmospheric dust module 304 is provided to the solar collection management module 200.

As shown in the illustrated embodiment of FIG. 7, a map 702 can represent different areas within the solar farm which may benefit from cloud seeding compared to the cost. Each area 704 on the map 702 represents a zone of the solar farm, which may in turn represent one or more banks of solar cells. Positive numbers represent a greater benefit from cloud seeding than the perceived cost, and so would merit cloud seeding under the conditions identified by the predictions.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “illustrative” is used herein to mean “serving as an example, instance or illustration.” Any embodiment or design described herein as “illustrative” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

Thus, a computer implemented method, system or apparatus, and computer program product are provided in the illustrative embodiments for managing participation in online communities and other related features, functions, or operations. Where an embodiment or a portion thereof is described with respect to a type of device, the computer implemented method, system or apparatus, the computer program product, or a portion thereof, are adapted or configured for use with a suitable and comparable manifestation of that type of device.

Where an embodiment is described as implemented in an application, the delivery of the application in a Software as a Service (SaaS) model is contemplated within the scope of the illustrative embodiments. In a SaaS model, the capability of the application implementing an embodiment is provided to a user by executing the application in a cloud infrastructure. The user can access the application using a variety of client devices through a thin client interface such as a web browser (e.g., web-based e-mail), or other light-weight client-applications. The user does not manage or control the underlying cloud infrastructure including the network, servers, operating systems, or the storage of the cloud infrastructure. In some cases, the user may not even manage or control the capabilities of the SaaS application. In some other cases, the SaaS implementation of the application may permit a possible exception of limited user-specific application configuration settings.

Embodiments of the present invention may also be delivered as part of a service engagement with a client corporation, nonprofit organization, government entity, internal organizational structure, or the like. Aspects of these embodiments may include configuring a computer system to perform, and deploying software, hardware, and web services that implement, some or all of the methods described herein. Aspects of these embodiments may also include analyzing the client's operations, creating recommendations responsive to the analysis, building systems that implement portions of the recommendations, integrating the systems into existing processes and infrastructure, metering use of the systems, allocating expenses to users of the systems, and billing for use of the systems. Although the above embodiments of present invention each have been described by stating their individual advantages, respectively, present invention is not limited to a particular combination thereof. To the contrary, such embodiments may also be combined in any way and number according to the intended deployment of present invention without losing their beneficial effects.

What is claimed is:

1. A computer-implemented method comprising:
constructing a model of atmospheric dust over a solar farm;
generating, using the model of the atmospheric dust, a solar irradiance prediction for a first area of the solar farm;
generating cell soiling data for the first area of the solar farm, the cell soiling data based on images of solar cells within the first area of the solar farm;
predicting, using the solar irradiance prediction and the cell soiling data as inputs to a prediction neural network, an initial solar collection prediction for the first area of the solar farm;
modifying the initial solar collection prediction based on an effect of cloud seeding on the first area of the solar farm to produce a modified solar collection prediction; and
sending, responsive to the modified solar collection prediction, an instruction for cloud seeding the first area of the solar farm.

2. The computer-implemented method of claim 1, further comprising:
calculating a cost for cloud seeding the first area of the solar farm; and
comparing the calculated cost to the modified solar collection prediction.

3. The computer-implemented method of claim 1, further comprising:
basing, as a part of the predicting, the initial solar collection prediction on geographic data for the first area of the solar farm.

4. The computer-implemented method of claim 1, further comprising:
basing, as a part of the predicting, the initial solar collection prediction on weather data for the first area of the solar farm.

5. The computer-implemented method of claim 1, further comprising:
basing, as a part of the generating, the solar irradiance prediction on satellite data of the first area of the solar farm.

6. The computer-implemented method of claim 5, further comprising:
producing, as a part of the generating, the solar irradiance prediction by a neural network provided with the satellite data of the first area of the solar farm.

7. The computer-implemented method of claim 6, further comprising:
training the neural network producing the solar irradiance prediction using a physics-informed constraint loss function.

8. The computer-implemented method of claim 1, further comprising:
producing, as part of the generating, the cell soiling data by a neural network provided with the images of the solar cells within the first area of the solar farm.

9. The computer-implemented method of claim 8, further comprising:
producing impact classification data by an impact classification network provided with the images of the solar cells within the first area of the solar farm; and
producing the cell soiling data by a localization network provided with the impact classification data from the impact classification network;
wherein the neural network comprises the impact classification network and the localization network.

10. The computer-implemented method of claim 1, further comprising:
generating, using the model of atmospheric dust, a solar irradiance prediction for a second area of a solar farm;
generating cell soiling data for the second area of the solar farm, the cell soiling data based on images of solar cells within the second area of the solar farm;
predicting, using the solar irradiance prediction and the cell soiling data as inputs to a prediction neural network, an initial solar collection prediction for the second area of the solar farm;
modifying the initial solar collection prediction for the second area of the solar farm based on an effect of cloud seeding on the second area of the solar farm to produce a modified solar collection prediction; and
sending, responsive to the modified solar collection prediction for the first and second areas of the solar farm, an instruction for cloud seeding the first area of the solar farm and not cloud seeding the second area of the solar farm.

11. The computer-implemented method of claim 10, further comprising:
calculating a cost for cloud seeding the first area of the solar farm;
calculating a cost for cloud seeding the second area of the solar farm;
for each of the first and second areas of the solar farm, comparing the calculated cost to the modified solar collection prediction; and
prioritizing cloud seeding the first area over cloud seeding the second area based on the comparisons.

12. A computer program product comprising one or more computer readable storage media, and program instructions collectively stored on the one or more computer readable storage media, the program instructions executable by a processor to cause the processor to perform operations comprising:
constructing a model of atmospheric dust over a solar farm;
generating, using the model of the atmospheric dust, a solar irradiance prediction for a first area of the solar farm;
generating cell soiling data for the first area of the solar farm, the cell soiling data based on images of solar cells within the first area of the solar farm;
predicting, using the solar irradiance prediction and the cell soiling data as inputs to a prediction neural network, an initial solar collection prediction for the first area of the solar farm;
modifying the initial solar collection prediction based on an effect of cloud seeding on the first area of the solar farm to produce a modified solar collection prediction; and
sending, responsive to the modified solar collection prediction, an instruction for cloud seeding the first area of the solar farm.

13. The computer program product of claim 12, wherein the stored program instructions are stored in a computer readable storage device in a data processing system, and wherein the stored program instructions are transferred over a network from a remote data processing system.

14. The computer program product of claim 12, wherein the stored program instructions are stored in a computer readable storage device in a server data processing system, and wherein the stored program instructions are downloaded in response to a request over a network to a remote data processing system for use in a computer readable storage device associated with the remote data processing system, further comprising:
program instructions to meter use of the program instructions associated with the request; and
program instructions to generate an invoice based on the metered use.

15. The computer program product of claim 12, further comprising:
basing, as a part of the predicting, the initial solar collection prediction on geographic data for the first area of the solar farm.

16. The computer program product of claim 12, further comprising:
basing, as a part of the generating, the solar irradiance prediction on satellite data of the first area of the solar farm.

17. The computer program product of claim 12, further comprising:
generating, using the model of atmospheric dust, a solar irradiance prediction for a second area of a solar farm;
generating cell soiling data for the second area of the solar farm, the cell soiling data based on images of solar cells within the second area of the solar farm;
predicting, using the solar irradiance prediction and the cell soiling data as inputs to a prediction neural network, an initial solar collection prediction for the second area of the solar farm;
modifying the initial solar collection prediction for the second area of the solar farm based on an effect of cloud seeding on the second area of the solar farm to produce a modified solar collection prediction; and
sending, responsive to the modified solar collection prediction for the first and second areas of the solar farm, an instruction for cloud seeding the first area of the solar farm and not cloud seeding the second area of the solar farm.

18. The computer program product of claim 17, further comprising:
calculating a cost for cloud seeding the first area of the solar farm;
calculating a cost for cloud seeding the second area of the solar farm;
for each of the first and second areas of the solar farm, comparing the calculated cost to the modified solar collection prediction; and
prioritizing cloud seeding the first area over cloud seeding the second area based on the comparisons.

19. A computer system comprising a processor and one or more computer readable storage media, and program instructions collectively stored on the one or more computer readable storage media, the program instructions executable by the processor to cause the processor to perform operations comprising:
constructing a model of atmospheric dust over a solar farm;
generating, using the model of the atmospheric dust, a solar irradiance prediction for a first area of the solar farm;
generating cell soiling data for the first area of the solar farm, the cell soiling data based on images of solar cells within the first area of the solar farm;
predicting, using the solar irradiance prediction and the cell soiling data as inputs to a prediction neural network, an initial solar collection prediction for the first area of the solar farm;
modifying the initial solar collection prediction based on an effect of cloud seeding on the first area of the solar farm to produce a modified solar collection prediction; and
sending, responsive to the modified solar collection prediction, an instruction for cloud seeding the first area of the solar farm.

20. The computer system of claim 19, further comprising:
generating, using the model of atmospheric dust, a solar irradiance prediction for a second area of a solar farm;
generating cell soiling data for the second area of the solar farm, the cell soiling data based on images of solar cells within the second area of the solar farm;
predicting, using the solar irradiance prediction and the cell soiling data as inputs to a prediction neural network, an initial solar collection prediction for the second area of the solar farm;
modifying the initial solar collection prediction for the second area of the solar farm based on an effect of cloud seeding on the second area of the solar farm to produce a modified solar collection prediction; and
sending, responsive to the modified solar collection prediction for the first and second areas of the solar farm, an instruction for cloud seeding the first area of the solar farm and not cloud seeding the second area of the solar farm.
